(19) United States
(12) Patent Application Publication
(10) Pub. No.: US 2024/0039234 A1
(43) Pub. Date: Feb. 1, 2024

(54) PULSED POWER CIRCUITS USING HYBRID NON-LINEAR MAGNETIC MATERIALS AND INDUCTORS INCORPORATING THE SAME

(71) Applicant: Cymer, LLC, San Diego, CA (US)

(72) Inventors: Yuda Wang, San Diego, CA (US); Paul Christopher Melcher, El Cajon, CA (US); Changqi You, San Diego, CA (US)

(21) Appl. No.: 18/268,378

(22) PCT Filed: Dec. 9, 2021
(86) PCT No.: PCT/US2021/062694

§ 371 Date: Jun. 20, 2023

Related U.S. Application Data
(60) Provisional application No. 63/129,188, filed on Dec. 22, 2020.

(51) Int. Cl. H01S 3/097; H03K 3/45; H01F 21/08; G03F 7/00

(52) U.S. Cl. CPC H01S 3/09702; H03K 3/45; H01F 21/08; G03F 7/70025

(57) ABSTRACT

A pulsed power circuit (30, 31, 32) including an inductor (55) having a hybrid core of a switch magnetic material arranged and selected to function as a magnetic switch a damping magnetic material arranged and selected to damp energy reflections without interfering with the switch magnetic material functioning as a magnetic switch so that the circuit can mitigate resonances caused by reflected energy without any significant degradation of its switching function as part of an saturable reactor inductor.

### CROSS REFERENCE TO RELATED APPLICATIONS

This application claims priority to U.S. Application No. 63/129,188, filed Dec. 22, 2020, titled PULSED POWER CIRCUITS USING HYBRID NON-LINEAR MAGNETIC MATERIALS AND INDUCTORS INCORPORATING THE SAME, which is incorporated herein in its entirety by reference.

### FIELD

The present disclosure relates to circuits for generating electrical pulses used in lasers to serve, for example, as illumination sources in lithographic apparatus.

### BACKGROUND

A lithographic apparatus applies a desired pattern onto a substrate such as a wafer of semiconductor material, usually onto a target portion of the substrate. A patterning device, which is alternatively referred to as a mask or a reticle, may be used to generate a circuit pattern to be formed on an individual layer of the wafer. Transfer of the pattern is typically accomplished by imaging onto a layer of radiation-sensitive material (resist) provided on the substrate. In general, a single substrate will contain adjacent target portions that are successively patterned.

Lithographic apparatus include so-called steppers, in which each target portion is irradiated by exposing an entire pattern onto the target portion at one time, and so-called scanners, in which each target portion is irradiated by scanning the pattern through a radiation beam in a given direction while synchronously scanning the substrate parallel or anti-parallel to this direction. It is also possible to transfer the pattern from the patterning device to the substrate by imprinting the pattern onto the substrate.

The light source used to illuminate the pattern and project it onto the substrate can be of any one of a number of configurations. Deep ultraviolet excimer lasers commonly used in lithography systems include the krypton fluoride (KrF) laser at 248 nm wavelength and the argon fluoride (ArF) laser at 193 nm wavelength.

Lasers such as those described use pulses of electrical energy. The circuits used to generate the electrical pulses typically include magnetic switching elements. These switching elements must be capable of generating pulses reproducibly and reliably.

It is in this context that the need for the present invention arises.

### SUMMARY

The following presents a simplified summary of one or more embodiments in order to provide a basic understanding of the embodiments. This summary is not an extensive overview of all contemplated embodiments and is not intended to identify key or critical elements of all embodiments nor delineate the scope of any or all embodiments. Its sole purpose is to present some concepts of one or more embodiments in a simplified form as a prelude to the more detailed description that is presented later.

According to an aspect of an embodiment there is disclosed a pulse power circuit for supplying pulses to a laser chamber, the pulse power circuit including an inductor having a hybrid saturable magnetic core predominantly comprising a switch magnetic material arranged and selected to function as a magnetic switch and secondarily comprising a damping magnetic material arranged and selected to damp reflections from the laser chamber without unduly interfering with the switch magnetic material's functioning as a magnetic switch. The materials may be such that when the inductor is biased to a bias point, a magnitude of a hysteresis magnetic permeability of the damping magnetic material at the bias point being greater than a magnitude of a hysteresis of the switch magnetic material at the bias point. The switch magnetic material may operate as a switch primarily in a switching range of the switch magnetic material, the switching range including field strengths between −H_{C} and +H_{C} of the switch magnetic material. The switch magnetic material may have a maximum magnetic permeability μ_{SWITCH} in the switching range which is much greater (e.g. >10×) than a maximum magnetic permeability μ_{DAMPER} of the damping magnetic material has in its own switching range. The switch magnetic material may have a first magnetic squareness ratio and the damping magnetic material has a second magnetic squareness ratio less than the first magnetic squareness ratio. The switch magnetic material may have a magnetic squareness ratio greater than 0.80. The damping magnetic material has a magnetic squareness ratio less than 0.80. The damping magnetic material may comprise a weight percentage of the saturable magnetic core in the range of 0.50% to 10%. The damping magnetic material may comprise a weight percentage of the saturable magnetic core on the order of 1%.

According to another aspect of an embodiment there is disclosed an inductor having a hybrid saturable magnetic core comprising a switch magnetic material arranged and selected to function as a magnetic switch and a damping magnetic material arranged and selected to damp reflections from the laser chamber without interfering with the first magnetic material's functioning as a magnetic switch. The materials may be chosen so that when the inductor is biased to a bias point, a magnitude of a hysteresis of the damping magnetic material at the bias point is greater than a magnitude of a hysteresis of the switch magnetic material at the bias point. The switch magnetic material operates primarily as a switch in a switching range including field strengths between −H_{C} and +H_{C} of the switch magnetic material, and the switch magnetic material has a minimum magnetic permeability μ_{SWITCH} in the switching range greater than a maximum magnetic permeability μ_{DAMPER} of the damping magnetic material in the switching range. The switch magnetic material may have a magnetic squareness ratio greater than 0.80. The damping magnetic material may have a magnetic squareness ratio less than 0.80. The damping magnetic material may comprise a weight percentage of the saturable magnetic core in the range of 0.5% to 10%. The damping magnetic material may comprise a weight percentage of the saturable magnetic core on the order of 1%.

According to another aspect of an embodiment there is disclosed an inductor comprising a plurality of first toroidal elements arranged in a stack, the first toroidal elements comprising a switch magnetic material arranged and selected to function as a magnetic switch and at least one second toroidal element arranged in the stack, the second toroidal element comprising a damping magnetic material arranged and selected to damp pulse energy reflections without interfering with the switch magnetic material functioning as a magnetic switch.

According to another aspect of an embodiment there is disclosed an inductor comprising a toroid formed of a tape-wound into one or more turns, the tape having a radial cross section when wound comprising at least one first layer made of a switch material selected to function as a magnetic switch and at least one second layer made of a damping material selected to damp pulse energy reflections without interfering with the switch magnetic material functioning as a magnetic switch.

According to another aspect of an embodiment there is disclosed a laser system comprising a laser chamber containing a pair of electrodes and a pulsed power supply system and arranged to supply pulses to the electrodes, the pulsed power system including a hybrid saturable core reactor, the hybrid saturable core reactor comprising a switch magnetic material arranged and selected to function as a magnetic switch and a damping magnetic material arranged and selected to damp reflections from the laser chamber without interfering with the switch magnetic material's functioning as a magnetic switch.

Further features and advantages of the present invention, as well as the structure and operation of various embodiments of the present invention, are described in detail below with reference to the accompanying drawings. It is noted that the present invention is not limited to the specific embodiments described herein. Such embodiments are presented herein for illustrative purposes only. Additional embodiments will be apparent to persons skilled in the relevant art(s) based on the teachings contained herein.

### BRIEF DESCRIPTION OF THE DRAWINGS

The accompanying drawings, which are incorporated herein and form part of the specification, illustrate the present invention and, together with the description, further serve to explain the principles of the present invention and to enable a person skilled in the relevant art(s) to make and use the present invention.

FIG. 1 is a functional block diagram of a pulse power circuit according to an aspect of an embodiment.

FIG. 2 is a circuit diagram for a commutator module such as could be used in the pulse power circuit of FIG. 1 according to an aspect of an embodiment.

FIG. 3A is a perspective view of a wound toroidal core.

FIG. 3B is a perspective cutaway view of the core of FIG. 3A taken along line BB.

FIG. 3C is a perspective view of a core made up of a cylindrical stack of toroidal core elements.

FIG. 4A is a diagram of magnetization curves for two materials according to an aspect of an embodiment.

FIG. 4B is another diagram of magnetization curve for two materials according to an aspect of an embodiment.

FIGS. 5A-E are perspective views of hybrid cores according aspects of embodiments.

The features and advantages of the present invention will become more apparent from the detailed description set forth below when taken in conjunction with the drawings, in which like reference characters identify corresponding elements throughout. In the drawings, like reference numbers generally indicate identical, functionally similar, and/or structurally similar elements.

### DETAILED DESCRIPTION

This specification discloses one or more embodiments that incorporate the features of this invention. The disclosed embodiment(s) merely exemplify the present invention. The scope of the present invention is not limited to the disclosed embodiment(s). The present invention is defined by the claims appended hereto.

The embodiment(s) described, and references in the specification to “one embodiment”, “an embodiment”, “an example embodiment”, etc., indicate that the embodiment(s) described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to effect such feature, structure, or characteristic in connection with other embodiments whether or not explicitly described.

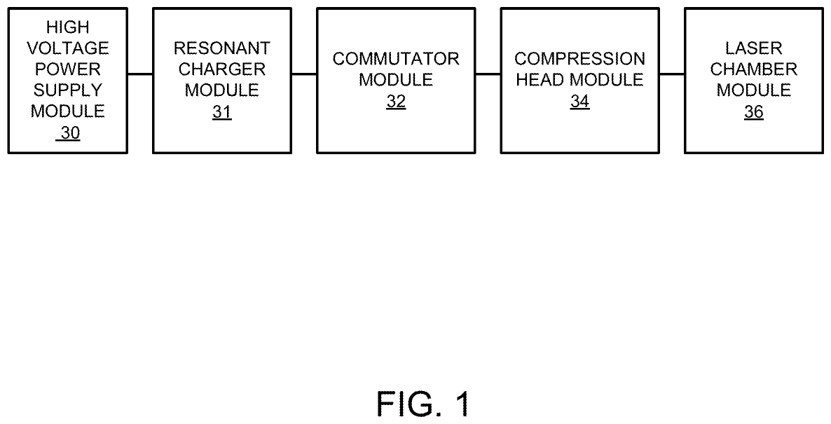

Turning to FIG. 1 there is shown an example of a pulse power circuit that includes a high voltage power supply module 30, a resonant charger module 31, a commutator module 32, a compression head module 34, and a laser chamber module 36. These components other than the laser chamber module 36 make up a solid state pulsed power module (SSPPM). High voltage power supply module 30 converts three phase normal plant power to a high DC voltage. The resonant charger 31 charges the capacitor banks in the commutator module 32 to increase the pulse voltage and form shorter electrical pulses. The compression head module 34 further temporally compresses the electrical pulses from the commutator module with a corresponding increase in current to produce pulses with the desired discharge voltage across the electrodes in the laser chamber module 36. Additional details of arrangement and operation of such a laser system can be found, for example, in U.S. Pat. No. 7,079,564, titled “Control System for a Two Chamber Gas Discharge Laser” issued Jul. 18, 2006, the entire contents of which are incorporated by reference herein. Further details on the operation of this circuitry may be found in U.S. Pat. No. 7,002,443, titled “Method and Apparatus for Cooling Magnetic Circuit Elements” issued Feb. 21, 2006, the entire contents of which are incorporated by reference herein.

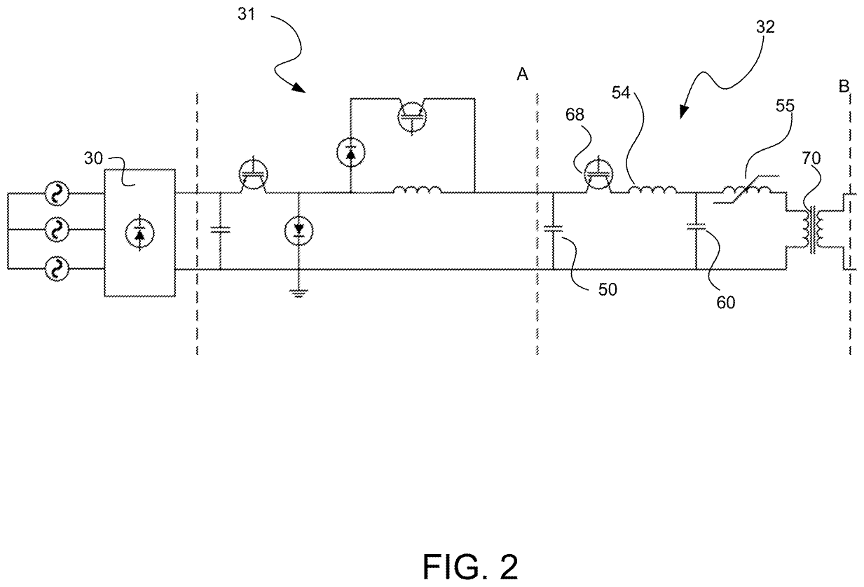

FIG. 2 is a simplified circuit diagram for a commutator module 32 such as could be used in the pulse power circuit of FIG. 1 according to an aspect of an embodiment. The elements between dashed lines A and B comprise the circuitry implementing the commutator module 32. The high voltage power supply module 30 supplies power to the resonant charger module 31 which operates in a known manner. The pulses from the resonant charger module 31 are supplied to commutator module 32 to charge capacitor 50. Capacitor 50 is usually referred to as C₀ and the voltage on capacitor 50 is referred to as V_{C0}. When a trigger signal is sensed the commutator solid state switch 68 closes, discharging the capacitor 50 to capacitor 60 through a charging inductance 54. Capacitor 60 is usually referred to as C₁ and the voltage on capacitor 60 is referred to as V_{C1}. The voltage is held on capacitor 60 until the saturable reactor 55, functioning as a magnetic switch, saturates and discharges capacitor 60 into a capacitor bank in the compression head module 34 through a transformer 70.

The saturable reactor 55 initially resists the flow of current from capacitor 60. More specifically, normally, before a pulse is fired, the saturable reactor 55 is biased to negative saturation. (The saturable reactor 55 can oppose incoming current even without a bias current but the bias current is used to provide an increased (even to a maximum) and stable flux swing.) When the next pulse energy comes from capacitor 50 to charge capacitor 60, the current induces an opposing electromotive force in the core of the saturable reactor 55 to oppose the incoming current until the core becomes saturated in the forward direction. Upon saturation the opposing electromotive force disappears, and the charge accumulated on capacitor 60 transfers as if a circuit switch has suddenly closed.

Saturable reactor 55 thus functions as a magnetic switch for the pulsed laser. The saturable magnetic core gives the inductor two states. In one state the inductance of the saturable reactor is high because the magnetic core has a high permeability. In the other state the inductance is low because the magnetic core has been driven into saturation, corresponding to a low permeability.

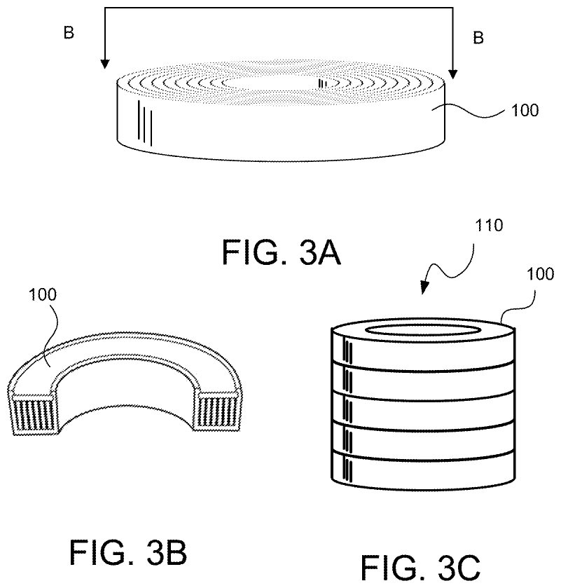

The magnetic core of the saturable reactor may be in any one of several forms including powder cores, ferrite cores, and tape-wound cores. An example of a tape-wound core 100 is shown in FIG. 3A. FIG. 3B is a cutaway view taken along line BB of FIG. 3A with an added casing, which may be made of aluminum, or similar structure or coating to mechanically stabilize the core. These tape-wound cores 100 may be used individually or may be arranged in a stack 110 as shown in FIG. 3C.

Tape-wound cores are made from thin strips of high permeability nickel-iron alloys including grain-oriented 50% nickel-iron alloys, non-oriented 80% nickel-iron alloy, and grain-oriented 3% silicon-iron alloy. These are some examples of materials. It will be apparent that the list is not exhaustive, and that many other materials may be used.

The cores for saturable reactors used in such an application have conventionally been required to exhibit a particular hysteresis squareness or Bᵣ/Bₛₐₜ ratio. This is because for ideal operation as a switch the core material should exhibit an almost square hysteresis curve as described more fully below. One characteristic of a square curve is that the knee in the curve where the magnetization B starts to fall off with decreasing (negative) field strength H is sharp.

One technical issue in the design of the power supply is the reflection of the pulse by the electrodes in the laser chamber module 36. These reflections can cause ringing that can interfere with the ability of the pulse circuitry to be ready to deliver the next pulse. Various measures have been employed to control this reflected energy. In this regard, see U.S. Pat. No. 5,729,562, titled “Pulse Power Generating Circuit with Energy Recovery” and issued Mar. 17, 1998, the entire specification of which is incorporated herein by reference.

According to an aspect of an embodiment, the reflected energy is further controlled by modifying the saturable reactor core to include, in addition to the “switch” magnetic material that dominates the switching behavior, a “damper” magnetic material with characteristics that cause the damping magnetic material to dampen out the reflected energy. The damping magnetic material is selected, however, so that it does not interfere with the switching operation of the switch magnetic material during pulse generation. This results in a hybrid core that performs both a switching function in pulse generation and a damping function after pulse generation. Here and elsewhere the term “interfere” is used to mean that while each of the magnetic materials may have some effect in the other's operational domain (switching v. damping), the out-of-domain effect is small enough that it does not unduly impede the function of the other material in its domain. Thus, the damping magnetic material does not interfere with the switching function of the switch magnetic material during switching, and the switch magnetic material does not interfere with the damping function of the damping magnetic material during reflection damping.

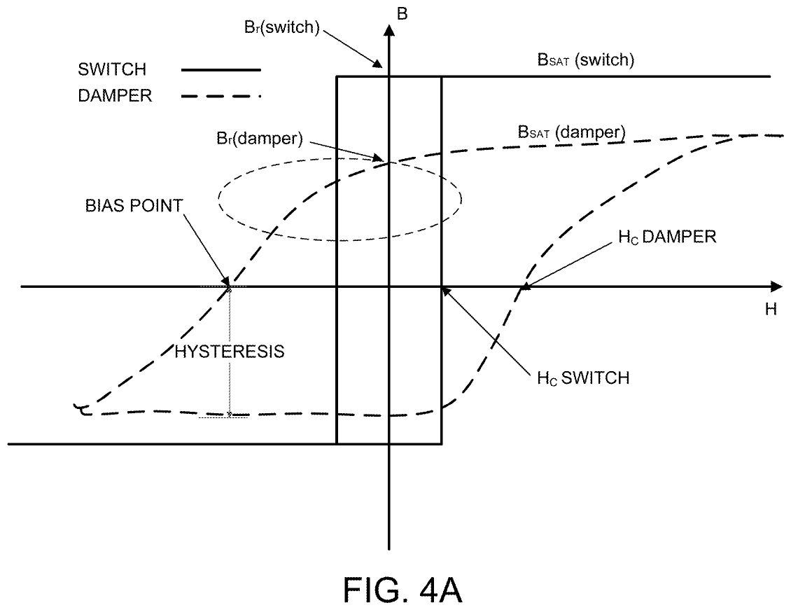

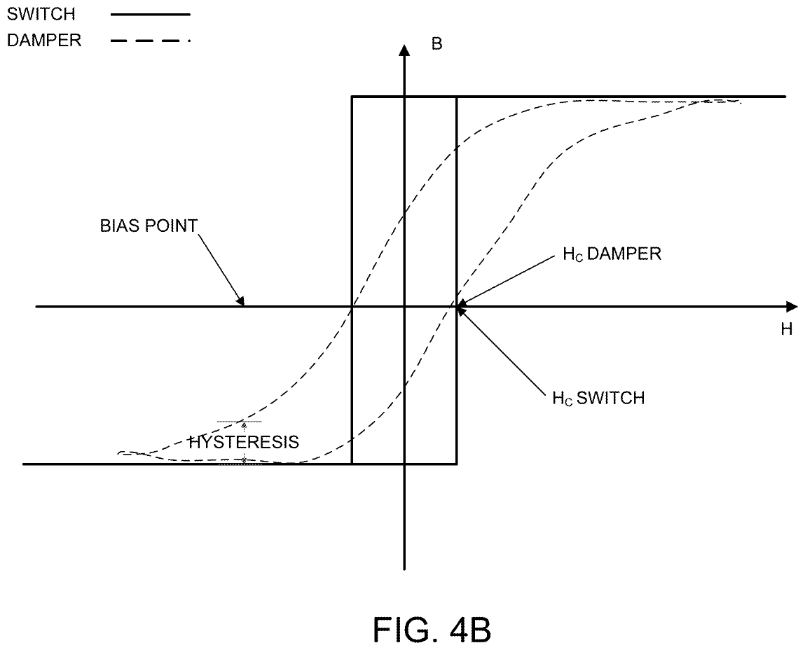

There are several ways of characterizing and selecting the damping magnetic material to achieve the desired end of reducing reflections without impairing switching. FIG. 4A shows an idealized hysteresis square curve (solid line) for the switch magnetic material. B_{SAT} (switch) on the figure is the saturation magnetism for the switch magnetic material, the point after which increasing the strength H of the applied magnetic field does not result in any increase in magnetization. B, (switch) is the B remanence of the switch, that is, the residual magnetization for the switch magnetic material when the strength of the strength of the applied H field drops to zero. For perfect squareness Br (switch)=B_{SAT} (switch) and their ratio is one. He relates to coercivity as explained in more detail below. The bias point is the point on the damper material curve (broken line) to which the core is biased.

According to an aspect of an embodiment, the advantages of using a high squareness material are retained for the switch magnetic material. Oscillations caused by reflected chamber energy are controlled, however, by adding a portion of lower squareness damping magnetic material to the core to create a hybrid core. As used herein, “hybrid” is intended to connote a combination of materials in which each material is discrete and distinct and retains its individual magnetic properties.

The broken line in FIG. 4A shows some possible characteristics of a damping magnetic material according to an aspect of an embodiment. B_{SAT} (damper) on the figure is the saturation magnetism for the damping magnetic material, the point after which increasing the strength H of the applied magnetic field does not result in any increase in magnetization. Bᵣ (damper) is the B remanence of the damper, that is, the residual magnetization for the damping magnetic material when the strength of the strength of the applied H field drops to zero. As can be seen, Bᵣ (damper)≠B_{SAT} (damper). According to an aspect of an embodiment, the low squareness material exhibits a rounded knee in the curve where the magnetization B starts to fall off with decreasing (negative) field strength H in the ellipse shown in a broken line.

According to an aspect of an embodiment the damping magnetic material is selected so that Bᵣ(damper)/B_{SAT}(damper)=Bᵣ(switch)/B_{SAT}(switch) where Bᵣ(damper) is the magnetic remanence of the damping magnetic material; B_{SAT}(damper) is the saturation or maximum magnetic strength of the damping magnetic material; Bᵣ(switch) is the magnetic remanence of the switch magnetic material; and B_{sAT}(switch) is the saturation or maximum magnetic strength of the switch magnetic material.

According to one aspect, the damping magnetic material is selected so that H_{C}(damper)>H_{C}(switch), where H_{C}(damper) is the coercivity of the damping magnetic material and H_{C}(switch) is the coercivity of the damping magnetic material. According to another aspect, even if H_{C}(damper) is small, the damping material can still damp out energy coming back from chamber if the curve around the knee point is relatively rounded as shown in the broken ellipse in FIG. 4A.

As can be seen in FIG. 4A, for the curve for the damper material hysteresis at the bias point that is larger than and dominates the hysteresis exhibited by the switch magnetic material at the bias point. Thus, the damping magnetic material can damp out reflected or residual energy from the laser chamber. The damping magnetic material, however, is near saturation in the switch operating range of the switch magnetic material (including between +H_{C} and −H_{C} for the switch magnetic material). In this range, the magnetic permeability μ_{S} of the switch magnetic material dominates the magnetic permeability μ_{D} of the damping magnetic material. This is particularly true where, according to an aspect of an embodiment, the amount of switch magnetic material dominates over the amount of damping magnetic material so that the presence of the damping magnetic material does not interfere with the operation of the switch magnetic material in that range.

In other words, according to an aspect of an embodiment, at the bias point the damping magnetic material hysteresis dominates the switch magnetic material hysteresis while in the switch operating range the magnetic permeability of the switch magnetic material dominates the magnetic permeability of the damping magnetic material. Thus, each material is effective in its own operational regime and does not interfere with the effectiveness of the other material in the other material's regime.

As another example, the broken line in FIG. 4B shows a possible hysteresis curve for another damping magnetic material. The damping magnetic material is selected so that Bᵣ(damper)/B_{SAT}(damper)<Bᵣ(switch)/B_{SAT}(switch). Also, the damping magnetic material is selected so that H_{C}(damper)=H_{C}(switch). A damping magnetic material having these characteristics yields the broken line hysteresis curve in FIG. 4B. As can be seen, the curve for the damper material again exhibits a hysteresis at the bias point that is much larger than the hysteresis exhibited by the switch magnetic material at the bias point. Thus, the damping magnetic material can damp out reflected or residual energy from the laser chamber. The magnetic permeability μ_{S} of the switch magnetic material dominates the magnetic permeability P_{D} of the damping magnetic material in the switch operating range. This is particularly true where, according to an aspect of an embodiment, the amount of switch magnetic material dominates over the amount of damping magnetic material so that the presence of the damping magnetic material does not interfere with the operation of the switch magnetic material in that range.

The number of materials may be two or more than two. In the example in which two materials make up the hybrid core material, the switch magnetic material can exhibit relatively high squareness while the damping magnetic material may exhibit a relatively low squareness. For some embodiments, the switch magnetic material may have a squareness in the range of 0.8 to 1. Also, for some embodiments, the damping magnetic material may have relatively low squareness may have a squareness less than 0.8.

According to another aspect of an embodiment, given a permeability ratio μₘₐₓ/μₛₐₜ for the switching material and a similarly defined permeability ratio for the damping material, respectively, it will be advantageous to have a relatively larger permeability ratio for the switching material and a relatively smaller permeability ratio for the damping material. Here p. is taken to be the slope of BH curve over switching region.

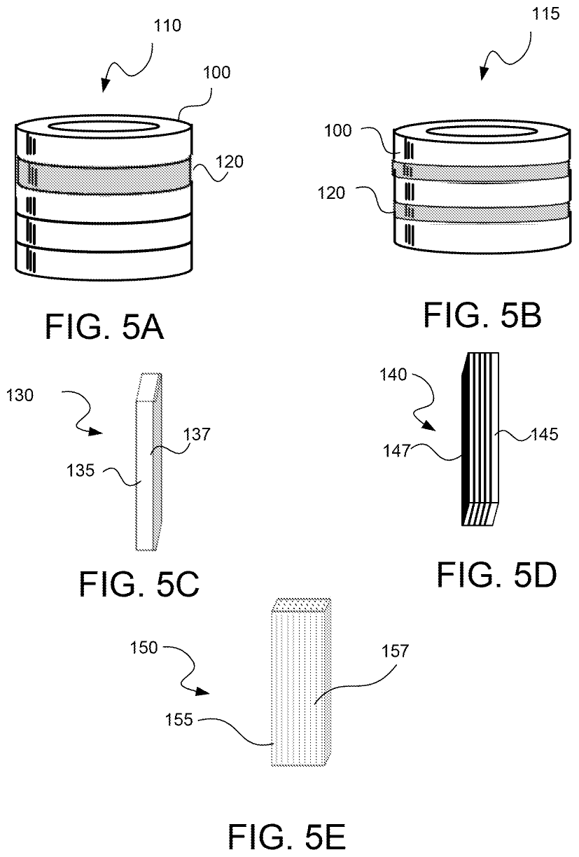

As regarding the physical structure of the magnetic core, as mentioned above the core can be configured as a cylindrical stack of toroidal elements. An example of this configuration is shown in FIG. 5. As can be seen, in the example the core is configured as a stack 110 of five toroidal elements although fewer or more elements may be used. In the stack, the lighter colored toroids, one of which is designated with numeral 100, is made of switch magnetic material. Together these toroids 100 comprise four of the five toroids in the stack 110. Inserted in the stack 110 is another toroid 120 made of the damping magnetic material. The toroid 120 may be placed at any position in the stack 110.

As shown in FIG. 5B, there may be multiple toroids of switch magnetic material 100 and damping magnetic material 120. Again, the toroids 120 may be placed at any position in the stack 110.

FIGS. 5C-5E are cross sections of the tape that is wound to make the toroids. As shown in FIG. 5C, a tape 130 may have a layer 135 of switch magnetic material with a layer 137 of damping magnetic material. The layers 135 and 137 may be positioned as shown, or the layer 137 may be below the layer 135 or sandwiched between two layers 135. As shown in FIG. 5D, a tape 140 may have multiple alternating layers 145 and 147 respectively of switch magnetic material and damping magnetic material, respectively. As shown in FIG. 5E, the low squareness material may be arranged in the tape 150 as an array of linear elements 157 in a matrix of high squareness material 155. The array may be regular as shown or irregular in terms of positioning and spacing of the elements.

The ratio by weight of the amount of damping magnetic material to damping magnetic material may be varied. For example, the amount of damping magnetic material by weight in the hybrid core may comprise 0.5 to 10 percent of the weight of the hybrid core. As another example, the hybrid core may comprise 1% damping magnetic material by weight.

Hybrid saturable magnetic cores such as those just described can be incorporated into inductors used as saturable core reactors in the pulse power circuitry described above.

While the foregoing description is primarily in terms of tape-wound cores for the sake of having a concrete example to facilitate a better understanding, it will be apparent to one of ordinary skill in the art that the principles set forth herein can also be applied to other types of cores.

It is to be appreciated that the Detailed Description section, and not the Summary and Abstract sections, is intended to be used to interpret the claims. The Summary and Abstract sections may set forth one or more but not all exemplary embodiments of the present invention as contemplated by the inventor(s), and thus, are not intended to limit the present invention and the appended claims in any way.

The present invention has been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The foregoing description of the specific embodiments will so fully reveal the general nature of the present invention that others can, by applying knowledge within the skill of the art, readily modify and/or adapt for various applications such specific embodiments, without undue experimentation, without departing from the general concept of the present invention. Therefore, such adaptations and modifications are intended to be within the meaning and range of equivalents of the disclosed embodiments, based on the teaching and guidance presented herein. It is to be understood that the phraseology or terminology herein is for the purpose of description and not of limitation, such that the terminology or phraseology of the present specification is to be interpreted by the skilled artisan in light of the teachings and guidance.

The embodiments can be further described using the following clauses:
1. A pulse power circuit for supplying pulses to a laser chamber, the pulse power circuit including an inductor having a hybrid saturable magnetic core comprising:
a switch magnetic material arranged and selected to function as a magnetic switch; and a damping magnetic material arranged and selected to damp reflections from the laser chamber without interfering with the switch magnetic material functioning as a magnetic switch.
2. A pulse power circuit of clause 1 wherein when the inductor is biased to a bias point, a magnitude of a hysteresis of the damping magnetic material at the bias point is greater than a magnitude of a hysteresis of the switch magnetic material at the bias point.
3. A pulse power circuit of clause 1 wherein the switch magnetic material operates as a switch primarily in a switching range of field strengths between −H_{C} and +H_{C} of the switch magnetic material, wherein the switch magnetic material has a minimum magnetic permeability μ_{SWITCH} in the switching range, and wherein the damping magnetic material has a maximum magnetic permeability μ_{DAMPER} in the switching range, and wherein μ_{DAMPER} is less than μ_{SWITCH}.
4. A pulse power circuit of clause 2 wherein the switch magnetic material operates as a switch primarily in a switching range of field strengths between −H_{C} and +H_{C} of the switch magnetic material, wherein the switch magnetic material has a minimum magnetic permeability μ_{SWITCH} in the switching range, and wherein the damping magnetic material has a maximum magnetic permeability μ_{DAMPER} in the switching range, and wherein μ_{DAMPER} is less than μ_{SWITCH}.
5. A pulse power circuit of clause 1 wherein the switch magnetic material has a first magnetic squareness ratio and the damping magnetic material has a second magnetic squareness ratio less than the first magnetic squareness ratio.
6. A pulse power circuit of clause 1 wherein the switch magnetic material has a magnetic squareness ratio greater than 0.80.
7. A pulse power circuit of clause 6 wherein the damping magnetic material has a magnetic squareness ratio less than 0.80.
8. A pulse power circuit of clause 1 wherein the damping magnetic material comprises a weight percentage of the saturable magnetic core in the range of 0.50% to 10%.9.
9. A pulse power circuit of clause 1 wherein the damping magnetic material comprises a weight percentage of the saturable magnetic core on the order of 1%.
10. An inductor having a hybrid saturable magnetic core comprising:
a switch magnetic material arranged and selected to function as a magnetic switch; and
a damping magnetic material arranged and selected to damp reflections from the laser chamber without interfering with the first magnetic material functioning as a magnetic switch.
11. An inductor of clause 10 wherein when the inductor is biased to a bias point, a magnitude of a hysteresis of the damping magnetic material at the bias point is greater than a magnitude of a hysteresis of the switch magnetic material at the bias point.
12. An inductor of clause 10 wherein the switch magnetic material operates as a switch primarily in a switching range of field strengths between −H_{C} and +H_{C} of the switch magnetic material, wherein the switch magnetic material has a minimum magnetic permeability μ_{SWITCH} in the switching range, and wherein the damping magnetic material has a maximum magnetic permeability μ_{DAMPER} in the switching range, and wherein μ_{DAMPER} is less than μ_{SWITCH}.
13. An inductor of clause 11 wherein the switch magnetic material operates as a switch primarily in a switching range of field strengths between −H_{C} and +H_{C} of the switch magnetic material, wherein the switch magnetic material has a minimum magnetic permeability μ_{SWITCH} in the switching range, and wherein the damping magnetic material has a maximum magnetic permeability μ_{DAMPER} in the switching range, and wherein μ_{DAMPER} is less than μ_{SWITCH}.
14. An inductor of clause 10 wherein the switch magnetic material has a first magnetic squareness ratio and the damping magnetic material has a second magnetic squareness ratio less than the first magnetic squareness ratio.
15. An inductor of clause 10 wherein the switch magnetic material has a magnetic squareness ratio greater than 0.8.
16. An inductor of clause 10 wherein the damping magnetic material has a magnetic squareness ratio less than 0.8.
17. An inductor of clause 10 wherein the damping magnetic material comprises a weight percentage of the saturable magnetic core in the range of 0.5% to 10%.
18. An inductor of clause 10 wherein the damping magnetic material comprises a weight percentage of the saturable magnetic core on the order of 1%.
19. An inductor comprising:
a plurality of first toroidal elements arranged in a stack, the first toroidal elements comprising a switch magnetic material arranged and selected to function as a magnetic switch; and
at least one second toroidal element arranged in the stack, the second toroidal element comprising a damping magnetic material arranged and selected to damp pulse energy reflections without interfering with the switch magnetic material functioning as a magnetic switch.
20. An inductor comprising:
a toroid formed of a tape wound into one or more turns, the tape having a radial cross section when wound comprising at least one first layer made of a switch material selected to function as a magnetic switch and at least one second layer made of a damping material selected to damp pulse energy reflections without interfering with the switch magnetic material functioning as a magnetic switch.
21. A laser system comprising:
a laser chamber containing a pair of electrodes; and
a pulsed power supply system arranged to supply pulses to the electrodes, the pulsed power system including a hybrid saturable core reactor, the hybrid saturable core reactor comprising a switch magnetic material arranged and selected to function as a magnetic switch and a damping magnetic material arranged and selected to damp reflections from the laser chamber without interfering with the switch magnetic material functioning as a magnetic switch.

Other embodiments and implementations are found within the scope of the following claims.

1. A pulse power circuit for supplying pulses to a laser chamber, the pulse power circuit including an inductor having a hybrid saturable magnetic core comprising:
a switch magnetic material arranged and selected to function as a magnetic switch; and
a damping magnetic material arranged and selected to damp reflections from the laser chamber without interfering with the switch magnetic material functioning as a magnetic switch.

2. A pulse power circuit as claimed in claim 1 wherein when the inductor is biased to a bias point, a magnitude of a hysteresis of the damping magnetic material at the bias point is greater than a magnitude of a hysteresis of the switch magnetic material at the bias point.

3. A pulse power circuit as claimed in claim 1 wherein the switch magnetic material operates as a switch primarily in a switching range of field strengths between −H_{C} and +H_{C} of the switch magnetic material, wherein the switch magnetic material has a minimum magnetic permeability μ_{SWITCH} in the switching range, and wherein the damping magnetic material has a maximum magnetic permeability μ_{DAMPER} in the switching range, and wherein μ_{DAMPER} is less than μ_{SWITCH}.

4. A pulse power circuit as claimed in claim 2 wherein the switch magnetic material operates as a switch primarily in a switching range of field strengths between −H_{C} and +H_{C} of the switch magnetic material, wherein the switch magnetic material has a minimum magnetic permeability μ_{SWITCH} in the switching range, and wherein the damping magnetic material has a maximum magnetic permeability μ_{DAMPER} in the switching range, and wherein μ_{DAMPER} is less than μ_{SWITCH}.

5. A pulse power circuit as claimed in claim 1 wherein the switch magnetic material has a first magnetic squareness ratio and the damping magnetic material has a second magnetic squareness ratio less than the first magnetic squareness ratio.

6. A pulse power circuit as claimed in claim 1 wherein the switch magnetic material has a magnetic squareness ratio greater than 0.80.

7. A pulse power circuit as claimed in claim 6 wherein the damping magnetic material has a magnetic squareness ratio less than 0.80.

8. A pulse power circuit as claimed in claim 1 wherein the damping magnetic material comprises a weight percentage of the saturable magnetic core in the range of 0.50% to 10%.

9. A pulse power circuit as claimed in claim 1 wherein the damping magnetic material comprises a weight percentage of the saturable magnetic core on the order of 1%.

10. An inductor having a hybrid saturable magnetic core comprising:
a switch magnetic material arranged and selected to function as a magnetic switch; and
a damping magnetic material arranged and selected to damp reflections from the laser chamber without interfering with the first magnetic material functioning as a magnetic switch.

11. An inductor as claimed in claim 10 wherein when the inductor is biased to a bias point, a magnitude of a hysteresis of the damping magnetic material at the bias point is greater than a magnitude of a hysteresis of the switch magnetic material at the bias point.

12. An inductor as claimed in claim 10 wherein the switch magnetic material operates as a switch primarily in a switching range of field strengths between −H_{C} and +H_{C} of the switch magnetic material, wherein the switch magnetic material has a minimum magnetic permeability μ_{SWITCH} in the switching range, and wherein the damping magnetic material has a maximum magnetic permeability μ_{DAMPER} in the switching range, and wherein μ_{DAMPER} is less than μ_{SWITCH}.

13. An inductor as claimed in claim 11 wherein the switch magnetic material operates as a switch primarily in a switching range of field strengths between −H_{C} and +H_{C} of the switch magnetic material, wherein the switch magnetic material has a minimum magnetic permeability μ_{SWITCH} in the switching range, and wherein the damping magnetic material has a maximum magnetic permeability μ_{DAMPER} in the switching range, and wherein μ_{DAMPER} is less than μ_{SWITCH}.

14. An inductor as claimed in claim 10 wherein the switch magnetic material has a first magnetic squareness ratio and the damping magnetic material has a second magnetic squareness ratio less than the first magnetic squareness ratio.

15. An inductor as claimed in claim 10 wherein the switch magnetic material has a magnetic squareness ratio greater than 0.8.

16. An inductor as claimed in claim 10 wherein the damping magnetic material has a magnetic squareness ratio less than 0.8.

17. An inductor as claimed in claim 10 wherein the damping magnetic material comprises a weight percentage of the saturable magnetic core in the range of 0.5% to 10%.

18. An inductor as claimed in claim 10 wherein the damping magnetic material comprises a weight percentage of the saturable magnetic core on the order of 1%.

19. An inductor comprising:
a plurality of first toroidal elements arranged in a stack, the first toroidal elements comprising a switch magnetic material arranged and selected to function as a magnetic switch; and
at least one second toroidal element arranged in the stack, the second toroidal element comprising a damping magnetic material arranged and selected to damp pulse energy reflections without interfering with the switch magnetic material functioning as a magnetic switch.

20. An inductor comprising:
a toroid formed of a tape wound into one or more turns, the tape having a radial cross section when wound comprising at least one first layer made of a switch material selected to function as a magnetic switch and at least one second layer made of a damping material selected to damp pulse energy reflections without interfering with the switch magnetic material functioning as a magnetic switch.

21. A laser system comprising:
a laser chamber containing a pair of electrodes; and
a pulsed power supply system arranged to supply pulses to the electrodes, the pulsed power system including a hybrid saturable core reactor, the hybrid saturable core reactor comprising a switch magnetic material arranged and selected to function as a magnetic switch and a damping magnetic material arranged and selected to damp reflections from the laser chamber without interfering with the switch magnetic material functioning as a magnetic switch.
